(19) United States
(12) Patent Application Publication
(10) Pub. No.: US 2008/0042662 A1
(43) Pub. Date: Feb. 21, 2008

(54) Method For Detecting Stent Coating Defects

(76) Inventor: George Abraham, Palo Alto, CA (US)

Correspondence Address: SQUIRE, SANDERS & DEMPSEY LLP, 1 MARITIME PLAZA, SUITE 300, SAN FRANCISCO, CA, 94111, US

(21) Appl. No.: 11/840,148

(22) Filed: Aug. 16, 2007

Related U.S. Application Data
(60) Provisional application No. 60/838,310, filed on Aug. 16, 2006.

(51) Int. Cl. G01R 27/02

(52) U.S. Cl. 324/693

(57) ABSTRACT

A coated medical device is connected to one pole of a detection device and is immersed in an electrolytic solution coupled to an oppositely charged pole of the detection device. An alert can be generated when a defect in the coating completes an electric circuit between the two poles of the detection device. The coating may include multiple layers, each layer contributing to the overall resistance of the coating. An alert can be generated when a partial defect, one which does not extend entirely through all the coating layers, or an unacceptable level of coating defects results in a decreased coating resistance coating or an increased current flow through the coating. The location of coating defects can be determined by monitoring for changes in resistance or current flow while the coated device is progressively lowered into the electrolytic solution.

This application claims the benefit of U.S. Provisional Application No. 60/838,310, filed Aug. 16, 2006, the entire disclosure of which is incorporated by reference.

### BACKGROUND OF THE INVENTION

1. Field of the Invention

This invention relates generally to medical device coatings and, more particularly, to detection of coating defects by electrical means.

2. Description of the State of the Art

Stents play an important role in a variety of medical procedures such as, for example, percutaneous transluminal coronary angioplasty. Blood vessel occlusions, blockages, or stenoses are commonly treated by mechanically enhancing blood flow in the affected vessels by positioning and deploying a stent inside the passageway of the vessel. Stents act as scaffoldings, functioning to physically hold open and, if desired, to expand the wall of the passageway.

Typically stents are capable of being compressed or crimped, so that they can be inserted through small anatomical passageways or lumens via catheters, and then expanded to a larger diameter once they are at a desired anatomical location. Examples in the patent literature disclosing stents include U.S. Pat. No. 4,733,665 to Palmaz, U.S. Pat. No. 4,800,882 to Gianturco, and U.S. Pat. No. 4,886,062 to Wiktor.

Thrombosis and restenosis may develop several months after a stent is deployed in a vessel and thereby require a surgical by-pass operation or additional angioplasty to be performed. To avoid additional angioplasty or surgical operation, medicated stents are being developed to elute anti-thrombotic and anti-restenosis agents. Stents may be used as vehicles for other types of therapeutic agents. For example, everolimus can be used in a drug-eluting stent as an immunosuppressant to prevent rejection of the stent or provide other biological therapy.

Medicated stents provide for the localized administration of a therapeutic substance at the diseased site. Local delivery of a therapeutic substance is often a preferred method of treatment because the substance is concentrated at a specific site and thus lower total levels of medication can be administered in comparison to systemic dosages that often produce adverse or even toxic side effects for the patient.

One method of medicating a stent involves the use of a polymeric carrier or reservoir coated onto the surface of the stent. The reservoir formed from a composition including a solvent, a polymer dissolved in the solvent, and a therapeutic substance dispersed in the blend. The composition is applied to the stent by immersing the stent in the composition or by spraying the composition onto the stent. The solvent is allowed to evaporate, leaving on the stent strut surfaces a coating of the polymer and the therapeutic substance impregnated in the polymer. A primer layer may be applied first to the stent to facilitate adhesion of a subsequently applied reservoir layer containing a therapeutic substance. Further, a stent can be coated with more than one reservoir layer, each having a different composition.

Defects in a stent coating can adversely affect therapeutic efficacy. For example, gaps or bare spots in the coating can decrease the amount of therapeutic substance a stent will deliver when deployed in a patient. Also, a small crack in the coating may result in a portion of the coating to detach or delaminate from the stent during subsequent crimping or expansion.

Existing methods of detecting defects in the coating include visual inspection using scanning electron microscopes, which are can be expensive to operate and maintain. Visual inspection is also time consuming and results of the inspection may not be available for hours or days. Such delays could allow several batches of stents to be coated with an unacceptable level of defects before corrective action is taken.

Commercially available testers for detecting coating defects, sometimes referred to as holiday testers, are used for checking coating defects in industrial pipes, buildings, civil works projects, chemical fluid storage tanks, and other large structures. Commercially available testers often use high voltages that result in a visible or audible spark or electrical discharge being generated when a probe of the tester comes upon a coating defect. The electrical discharge may damage or degrade a medical device coating, which can be as thin as one micron, making such testers unsuitable. In addition, commercially available testers lack the sensitivity to distinguish between, on one hand, coating defects that penetrate entirely through a coating and expose the coated substrate and, on the other hand, partial coating defects that penetrate only partially through the coating and do not expose the coated substrate.

Therefore, there is a need for a method and system of detecting coating defects that is quick and less expensive. There is also a need for a reliable and non-destructive method and system for detecting coating defects. Further, there is a need for a method and system for detecting different types of coating defects in multi-layer coatings, such as defects that penetrate a reservoir layer to expose a primer layer and defects that penetrate entirely through all coating layers. The present invention satisfies these and other needs.

### SUMMARY OF THE INVENTION

Briefly and in general terms, the present invention is directed to methods and systems for detecting coating defects. A method for detecting coating defects on a stent comprises monitoring for electrical current between a conductive medium and a substrate of a stent, the substrate covered by a coating, the conductive medium on an outer surface of the stent. In other aspects of the present invention, the method further comprises placing the conductive medium on the outer surface of the stent. In yet other aspects, the method further comprises connecting an electrode to the substrate, and connecting an oppositely charged electrode to the conductive medium.

In detailed aspects of the present invention, the conductive medium is a liquid. In other detailed aspects, the method further comprises detecting an electrical current between the conductive medium and the substrate, the electrical current indicative of a defect in the coating. In further aspects, the coating has a nominal thickness at or below about six microns. In other further aspects, the defect is an outer surface of the substrate not covered by the coating.

The coating, in other aspects of the present invention, includes a first layer and a second layer covering the first layer, and the defect is an outer surface of the first layer not covered by the second layer. In detailed aspects, the first layer includes a primer material and the second layer includes either one or both of a polymeric material and a therapeutic agent.

The method, in yet other aspects of the present invention, further comprises detecting an electrical current between the conductive medium and the substrate, and comparing the detected current to a limit value representative of a defect in the coating. In other aspects, the method further comprises mapping electrical current versus position of the medium on the stent.

A method for detecting coating defects on a medical device, in other aspects of the present invention, comprises placing at least a portion of a coated medical device in a liquid, and determining whether an unacceptable defect level exists in a coating covering a substrate of the medical device based at least on an electrical parameter of the coating.

In detailed aspects of the present invention, the electrical parameter is a resistance value. In other detailed aspects, the electrical parameter is an amount current capable of flowing through the coating when a voltage is applied across the substrate and the liquid.

The method, in other aspects of the present invention, comprises applying a voltage across the substrate and the liquid. In yet other aspects, the method further comprises comparing the electrical parameter to a limit value corresponding to the unacceptable defect level.

In other aspects of the present invention, the unacceptable defect level is determined to exist in the coating when the electrical parameter has a level representative of contact between the substrate and the liquid.

The coating, in further aspects of the present invention, includes a first layer and a second layer covering the first layer. In still further aspects, the unacceptable defect level is determined to exist in the second layer when the electrical parameter has a level representative of contact between the first layer and the liquid.

A system for detecting coating defects, in aspects of the present invention, comprises an electrically conductive medium capable of conforming to an outer surface of a coated stent, and a device coupled to the conductive medium and a substrate of the coated stent, the device capable of sensing an electrical current across a first coating layer covering the substrate, the sensed current representative of a defect in a second coating layer covering the first coating layer.

In other aspects, the system further comprises a power source coupled to the conductive medium and the substrate. In detailed aspects, the conductive medium includes an electrolytic solution. In further aspects, the first coating layer is about one micron thick.

The features and advantages of the invention will be more readily understood from the following detailed description which should be read in conjunction with the accompanying drawings.

### BRIEF DESCRIPTION OF THE DRAWINGS

FIG. 1 is a diagram of a system for detecting stent coating defects, the diagram showing a detection device coupled to an electrically conductive medium.

FIG. 2 is a perspective view of a stent showing a plurality of radially expandable struts interconnected by connecting members.

FIG. 3 is a diagram of the system of FIG. 1 showing the detection device coupled to the stent immersed in the electrically conductive medium.

FIG. 4 is a cross-sectional view of a portion of the stent of FIG. 3 showing a substrate covered by a first layer, a second layer surrounding the first layer, a connector attached to the substrate, and a coating defect exposing the substrate.

FIG. 5 is a cross-sectional view of a portion of a stent showing a substrate covered by a first layer, a second layer covering the first layer, a connector attached to the substrate, and a coating defect exposing the first layer.

FIG. 6 is a diagram of a system for detecting stent coating defects, the diagram showing the detection device of FIG. 1 coupled to the stent of FIG. 5, an apparatus for moving the stent in relation to the conductive medium, and a mapping device coupled to the detection device and the apparatus.

FIG. 7 is a diagram of resistance and current as a function of longitudinal location on the stent of FIG. 6, the diagram showing resistance and current changes indicative of coating defects.

FIG. 8 is a diagram of a system for detecting various types of coating defects, the diagram showing a power source coupled to a stent and a conductive medium, a knob for adjusting the system to detect a selected type of coating defect, and a measuring device coupled to the power source.

FIG. 9 is a diagram showing a method for detecting coating defects.

### DETAILED DESCRIPTION OF THE INVENTION

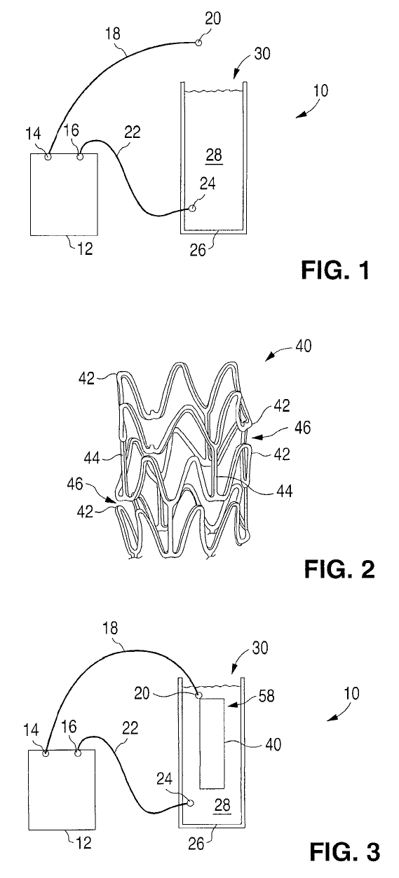

Referring now in more detail to the exemplary drawings for purposes of illustrating embodiments of the invention, wherein like reference numerals designate corresponding or like elements among the several views, there is shown in FIG. 1 a system 10 for detecting stent coating defects. The system includes a detection device 12 having a first pole 14 and an oppositely charged second pole 16. A first insulated wire or lead 18 is connected to the first pole 14. At the opposite end of the first lead 18, there is a first electrode 20 adapted to attach to a stent. The electrode 20 can include a clamp, clip, or other connector. A second insulated wire or lead 22 is connected to the second pole 16. A second electrode 24 located at the opposite end of the second lead 22 is disposed within a container 26 carrying an electrically conductive medium 28, such as an electrolyte solution. Suitable electrolyte solutions include, without limitation, water having weak ions, a low-salt saline solution, and other solutions having a salinity or ionic strength that allows the solution to be electrically conductive. The container has an opening 30 sized to allow a stent to pass through it.

FIG. 2 illustrates a portion of an exemplary stent 40 formed from a plurality of struts 42. The plurality of struts 42 are radially expandable and interconnected by connecting elements 44 that are disposed between adjacent struts, leaving lateral gaps or openings 46 between adjacent struts. Struts 42 and connecting elements 44 define a tubular stent body having an outer, tissue-contacting surface and an inner surface. The struts 42 and the connecting elements 44 can be formed from a metal, such as Nitinol, or other electrically conductive material. The conductive material functions as a substrate on which a coating is applied.

FIG. 3 shows the detection device 12 connected to the stent 40, which is illustrated schematically for ease of illustration. The connector 20 of the first lead 18 can be attached to one of the struts 42 or connecting elements 44 of the stent 40, preferably at or near one end of the stent.

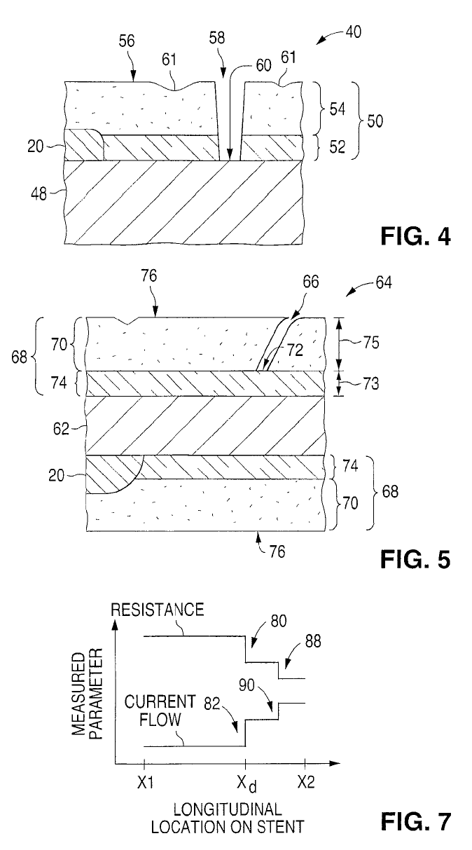

As shown in FIG. 4, the connector 20 is in contact with an electrically conductive substrate 48 of the stent 40. Covering the substrate 48 is a coating 50 comprising a primer layer 52 and a reservoir layer 54. The reservoir layer 54 forms at least a portion of the outer surface 56 of the stent 40. A coating defect 58, in the form of a gap, extends entirely through the coating 50 and exposes a portion of an upper surface 60 of the conductive substrate 48. In other embodiments, the defect can be in the form of a thin crack or crevice.

Referring again to FIG. 3, the stent 40 is immersed in the electrically conductive medium 28. The medium 28 conforms to the outer surface 56 (FIG. 4) of the stent 40 and enters depressions 61 and gaps in the coating 50, including the coating defect 58. Because of the coating defect 58, the medium 28 makes electrical contact with the upper surface 60 of the substrate 48. Such contact completes an electrical circuit between the first and second poles 14, 16 of the detection device 12. Upon completion of the circuit, the detection device 12 provides an alert indicating the existence of the defect 58.

In FIG. 5, there is shown another embodiment of the present invention in which the connector 20 of the detection device 12 of FIG. 1 is attached to a substrate 62 of a coated stent 64. The stent 64 has a coating defect 66 in the form of a gap partially extending through a multi-layer coating 68. The gap extends through a reservoir layer 70, but not through an underlying primer layer 74. Thus, the gap exposes a portion 72 of the primer layer 74 such that an outer surface of the stent 76 includes the exposed portion 72.

The primer layer 74 has a nominal thickness 73 of about one micron and has a known or expected resistance, Rp, which can vary depending upon the resistivity or conductivity of the material composition of the primer layer. The reservoir layer 70 can be greater than about one micron in thickness, and can have a nominal thickness 75 from about two microns to about five microns. The coating combination of the primer layer 74 and the reservoir layer 70 has a known or expected resistance, Rpr, which is greater than Rp.

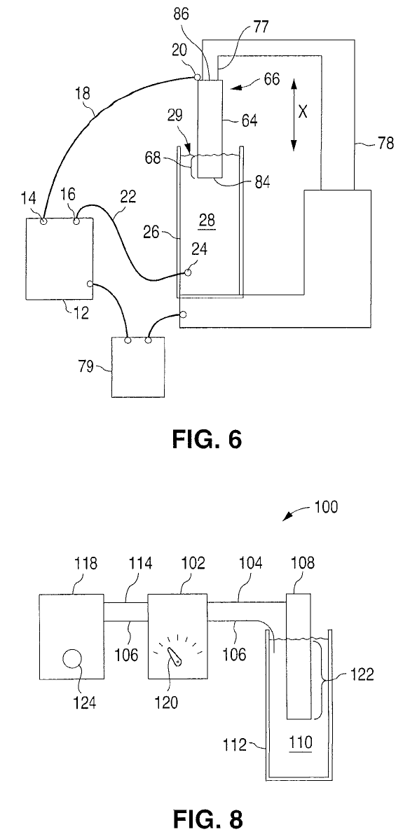

Referring next to FIG. 6, the coated stent 64 and the container 26 are attached to an apparatus 78 that allows the stent 64 and the container 26 to be moved in relation to one another. The stent 64 is mounted on a mandrel 77 of the apparatus 78. The mandrel 77 extends into the central lumen of the stent 64. The mandrel 77 may include hooks for supporting the stent 64. As the stent 64 is lowered into the container 26 or as the container 26 is raised up to the stent 64, the medium 28 conforms to the outer surface 76 of the stent 64 and enters any depressions and gaps in the coating 68. The detection device 12 continuously monitors or periodically samples the resistance provided by the coating portion in contact with the medium 28. The resistance provided can be determined from the presence or amount of current flow between the two poles 14, 16 of the detection device 12. The detection device 12 is configured to provide no alert when the resistance is at about Rpr and to provide an alert when the resistance is at a level below Rpr. When there is no defect in the coating portion in contact with the medium 28, the monitored resistance will at about Rpr and no alert with be produced by the detection device 12.

As the stent 64 is lowered further into the container 26 or as the container 26 is raised further onto the stent 64, the medium 28 enters the reservoir layer defect 66 and makes contact with the upper surface 72 of the primer layer 74. As a result, current flow increases and the monitored resistance drops to Rp, which is below Rpr. When the monitored resistance drops below Rpr or reaches Rp, the detection device 12 provides an alert indicating the presence of the reservoir layer defect 66 near the top surface 29 of the medium 28.

Referring now to FIG. 7, the location of the reservoir layer defect 66 on the stent 64 can be determined by mapping a measured parameter versus the instantaneous position of the stent in relation to the top surface 29 of the medium 28. The measured parameter can be resistance or current. Mapping can be automatically performed by device 77, such as a personal computer running data acquisition software, coupled to the detection device 12 and the apparatus 78. A drop 80 in resistance or a rise 82 in current flow between the first and second poles 14, 16 of the detection device 12 would mark the longitudinal location of the reservoir layer defect 66. In FIG. 7, X1 denotes an end 84 (FIG. 6) of the stent 64 that is first to enter the medium 28, X2 denotes the opposite end 86 of the stent, and Xd denotes the relative location of the reservoir layer defect 66 between X1 and X2. A subsequent drop 88 in resistance or rise 90 in current flow would mark the longitudinal location of another defect, such as a gap extending through the primer layer 74 and the reservoir layer 70. Thus, it will be appreciated that the detection system is capable of distinguishing between coating defects that penetrate only partially through the coating without exposing the coated substrate and those that penetrate entirely through a coating to expose the coated substrate.

Although some embodiments of the present invention have been described in terms of a stent, it is to be understood that the present invention encompasses other medical devices and prostheses having coatings.

In FIG. 8, a system 100 for detecting medical coating defects is shown in accordance with an embodiment of the present invention. The system includes a power source 102 having a first lead 104 and a second lead 106. The first lead 104 is in electrical communication with the substrate of a coated medical device 108. The substrate is covered by a medical coating having a nominal coating thickness on the order of several microns. The second lead 106 is in electrical communication with a conductive medium 110 held in an open container 112. Since electrical variables, such as resistivity and conductivity, can be temperature dependant, the container 112 is thermally insulated and the conductive medium 110 is maintained at a selected temperature to ensure accuracy of the system 100 in detecting medical coating defects. A third lead 114 and a fourth lead 116 connect the power source 102 to a measuring device 118.

The power source 102 includes a voltage source having one pole connected to ground and an opposite pole connected to the medical device 108 via the first lead 104. The opposite pole is also connected to a first leg of an electronic resistance bridge circuit within the power source 102. The first leg includes a variable resistor, such as a potentiometer, linked to an externally located knob 120 or other device that allows a user of the system 100 to adjust or tune the system to detect various types of coating defects, as will be described in further detail below. The amount of electrical current that flows from the voltage source through the first leg of the resistance bridge is a function of the electrical resistance of the first leg, which is adjusted with the variable resistor.

The second lead 106 coming from the container 112 is connected to a second leg of the electronic resistance bridge circuit within the power source 102. The electrical current that that flows through the second leg of the resistance bridge corresponds to current flow through the first lead 104, medical device 108, medium 110, and the second lead 106. The amount of electrical current that flows through the second leg of the resistance bridge is a function of the resistance provided by the immersed portion 122 of the medical device coating.

The first and second legs of the resistance bridge are connected by the third and fourth leads 114, 116, respectively, to a comparator within the measuring device 118. The comparator triggers activation of an indicator 124, such as a light source or a buzzer, on the device 118 when the current through the second leg of the resistance bridge is greater than the current through the first leg of the resistance bridge. This condition occurs when the resistance of the immersed portion 22 of the coating is less than the resistance of the first leg.

In use, a user of the system 100 moves the knob 120 such that the first leg of the resistance bridge within the power source 102 has a selected resistance. For example, the selected resistance can be the known or expected resistance, Rexp, of a particular type of medical device coating having no defects. The comparator of the measuring device 118 will trigger activation of the indicator 124 when the resistance of the immersed portion 22 of the coating is below Rexp, thus alerting the user that a coating defect is present on the stent 108. As a further example, the selected resistance can be set to the expected resistance of a particular coating having an unacceptable level of defects so that the indicator 124 will alert the user when an unacceptable level of defects exists on the medical device 108. The selected resistance functions as a test limit or threshold that may be adjusted using the knob 120. In another example, the selected resistance can be set to the expected resistance of a first layer of the medical device coating such that the indicator 124 will alert the user when there is a coating defect in the form of a gap in a second layer above the first layer. The selected resistance can also be set to the expected resistance of a first and second layer combination of a multi-layer coating so that the user can be alerted when there is a coating defect in a third layer above the first and second layers.

In another embodiment, the power source 102 and the measuring device 118 are combined as one unit. Other embodiments may employ a combination imaging and current measuring device, such as an oscilloscope, to map the entire surface of a coated medical device. Other types of circuitry and electronic devices can be employed to monitor, measure, and map resistance or electric current in order to detect and locate coating defects without departing from the scope of the invention. The electrically conductive medium of other embodiments can include, without limitation, brushes, sponges, and resilient structures that facilitate or provide electrical contact at a medical coating defect.

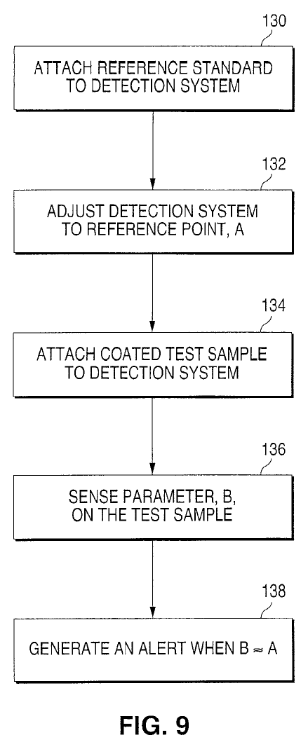

FIG. 9 shows a method in accordance with an embodiment of the present invention. A reference standard is attached 130 to a detection system for detecting coating defects. The system can include the detection device 12 of FIG. 1, the power source 102 and measuring device 118 of FIG. 8, or other devices. Examples of reference standards include, without limitation, a device simulating a multi-layer stent coating have no defects, a device having a resistance equivalent to the resistance of a primer layer, and a stent immersed in an electrolytic solution, the stent having a threshold level of coating defects. The detection system is adjusted 132 to a reference point, A, provided by the reference standard so that an alert is provided when a parameter of a test sample corresponds to the reference point. The adjustment can be accomplished by adjusting a variable resistor, or by other means.

Still referring to FIG. 9, the reference standard is removed and a portion of a test sample is attached 134 to the detection system. An non-limiting example of a test sample is a medical device having a coating with a selected area of the coating coupled to the detection system. The selected area of the coating can be immersed in a temperature-controlled electrolyte solution or brought into contact with a conductive medium that conforms to an outer surface of the coating. A parameter, B, of the attached portion of the test sample is sensed 136. Examples of test parameters include, without limitation, resistance, resistivity, current flow, conductivity, and other electrical variables. An alert is generated 138 when the sensed parameter, B, is at a level that corresponds to the reference point, A, of the detection system. The alert can indicate whether the attached portion of the test sample has a coating defect or an unacceptable level of coating defects.

In another embodiment, a limit value is entered into the detection system instead of using the reference standard. Examples of limit values that may be used include, without limitation, the resistivity of a multi-layer stent coating have no defects or an unacceptable level of defects, and the conductivity of a primer layer. The limit value can be entered directly via a keypad or a knob. The alert is generated when the parameter of the test sample reaches or exceeds the limit value.

In other embodiments, the parameter is sensed over different portions or over an ever increasing portion of the test sample. The sensed parameter is plotted or mapped in relation to portions of the test sample. The location of any coating defects is determined from the mapping.

While several particular forms of the invention have been illustrated and described, it will also be apparent that various modifications can be made without departing from the scope of the invention. It is also contemplated that various combinations or subcombinations of the specific features and aspects of the disclosed embodiments can be combined with or substituted for one another in order to form varying modes of the invention. Accordingly, it is not intended that the invention be limited, except as by the appended claims.

What is claimed is:

1. A method for detecting coating defects on a stent, the method comprising:
monitoring for electrical current between a conductive medium and a substrate of a stent, the substrate covered by a coating, the conductive medium on an outer surface of the stent.

2. The method of claim 1, further comprising placing the conductive medium on the outer surface of the stent.

3. The method of claim 1, further comprising connecting an electrode to the substrate, and connecting an oppositely charged electrode to the conductive medium.

4. The method of claim 1, wherein the conductive medium is a liquid.

5. The method of claim 1, further comprising detecting an electrical current between the conductive medium and the substrate, the electrical current indicative of a defect in the coating.

6. The method of claim 5, wherein the coating has a nominal thickness at or below about six microns.

7. The method of claim 5, wherein the defect is an outer surface of the substrate not covered by the coating.

8. The method of claim 5, wherein the coating includes a first layer and a second layer covering the first layer, and the defect is an outer surface of the first layer not covered by the second layer.

9. The method of claim 8, wherein the first layer includes a primer material and the second layer includes either one or both of a polymeric material and a therapeutic agent.

10. The method of claim 1, further comprising detecting an electrical current between the conductive medium and the substrate, and comparing the detected current to a limit value representative of a defect in the coating.

11. The method of claim 1, further comprising mapping electrical current versus position of the medium on the stent.

12. A method for detecting coating defects on a medical device, the method comprising:
placing at least a portion of a coated medical device in a liquid; and
determining whether an unacceptable defect level exists in a coating covering a substrate of the medical device based at least on an electrical parameter of the coating.

13. The method of claim 12, wherein the electrical parameter is a resistance value.

14. The method of claim 12, wherein the electrical parameter is an amount current capable of flowing through the coating when a voltage is applied across the substrate and the liquid.

15. The method of claim 12, further comprising applying a voltage across the substrate and the liquid.

16. The method of claim 12, further comprising comparing the electrical parameter to a limit value corresponding to the unacceptable defect level.

17. The method of claim 12, wherein the unacceptable defect level is determined to exist in the coating when the electrical parameter has a level representative of contact between the substrate and the liquid.

18. The method of claim 12, wherein the coating includes a first layer and a second layer covering the first layer.

19. The method of claim 18, wherein the unacceptable defect level is determined to exist in the second layer when the electrical parameter has a level representative of contact between the first layer and the liquid.

20. A system for detecting coating defects, the system comprising:
an electrically conductive medium capable of conforming to an outer surface of a coated stent; and
a device coupled to the conductive medium and a substrate of the coated stent, the device capable of sensing an electrical current across a first coating layer covering the substrate, the sensed current representative of a defect in a second coating layer covering the first coating layer.

21. The system of claim, 20 further comprising a power source coupled to the conductive medium and the substrate.

22. The system of claim 20, wherein the conductive medium includes an electrolytic solution.

23. The system of claim 20, wherein the first coating layer is about one micron thick.
